(19) United States
(12) Patent Application Publication
(10) Pub. No.: US 2025/0286017 A1
(43) Pub. Date: Sep. 11, 2025

(54) SEMICONDUCTOR DEVICE

(71) Applicant: SAMSUNG ELECTRONICS CO., LTD., Suwon-si (KR)

(72) Inventors: Byeongcheol Park, Suwon-si (KR); Hyounsoo Park, Suwon-si (KR)

(21) Appl. No.: 18/819,793

(22) Filed: Aug. 29, 2024

(30) Foreign Application Priority Data
Mar. 5, 2024 (KR) 10-2024-0031562

(51) Int. Cl. H01L 25/065; H01L 23/00; H01L 27/02

(52) U.S. Cl. CPC H01L 25/0657; H10D 89/10; H01L 24/16; H01L 2224/16148; H01L 2225/06513; H01L 2225/06541; H01L 2225/06596; H01L 2924/1431

(57) ABSTRACT

A semiconductor device includes a lower semiconductor die including a plurality of lower elements, a lower interconnection region, and a plurality of lower via structures, and an upper semiconductor die including a plurality of upper elements, and an upper interconnection region, the upper semiconductor die stacked on the lower semiconductor die in one direction. Some lower elements, among the plurality of lower elements, and some upper elements, among the plurality of upper elements, provide a first ring oscillator outputting a reference clock signal generated through a signal transmission path including first via structures that are some lower via structures, among the plurality of lower via structures, and a second ring oscillator outputting a test clock signal generated through a signal transmission path including second via structures different from the first via structures, among the plurality of via structures.

### CROSS-REFERENCE TO RELATED APPLICATION(S)

This application claims benefit of priority to Korean Patent Application No. 10-2024-0031562, filed on Mar. 5, 2024, in the Korean Intellectual Property Office, the entirety of which is incorporated herein by reference.

### BACKGROUND

A semiconductor device may include various circuits necessary to perform computation. In order to improve performance of semiconductor devices and reduce power consumption of semiconductor devices, a three-dimensional (3D) semiconductor device has been proposed, in which circuits included in the semiconductor device are distributed across a plurality of semiconductor dies and the semiconductor dies are stacked. In a 3D semiconductor device, at least some circuits, among circuits included in different semiconductor dies, may be connected to each other through via structures to exchange data signals, clock signals, and the like.

### SUMMARY

Because of the high degree of interconnectivity of modern semiconductor devices, it can be beneficial, in order to improve reliability and a degree of integration of 3D semiconductor devices, to accurately determine delay characteristics of a signal between semiconductor dies stacked on each other.

Some aspects of the present disclosure improve reliability of a semiconductor device including semiconductor dies connected by via structures and stacked on each other by accurately determining delay characteristics of a signal transmitted between the semiconductor dies.

According to some implementations, there is provided a semiconductor device including a lower semiconductor die including a lower substrate, a plurality of lower standard cells disposed on the lower substrate, a plurality of via structures passing through the lower substrate, and a plurality of pads exposed externally, and an upper semiconductor die including an upper substrate and a plurality of upper standard cells disposed on the upper substrate, the upper semiconductor die stacked on the lower semiconductor die. Some standard cells, among the plurality of lower standard cells and the plurality of upper standard cells, may provide a first logic gate and a second logic gate. The first logic gate, first lower reference cells among the plurality of lower standard cells, first upper reference cells among the plurality of upper standard cells, and first via structures among the plurality of via structures may provide a first ring oscillator. The second logic gate, second lower reference cells among the plurality of lower standard cells, second upper reference cells among the plurality of upper standard cells, second via structures among the plurality of via structures, and a test circuit connected between the second via structures and an input terminal of the second logic gate may provide a second ring oscillator. The first ring oscillator may output a reference clock signal to a first pad among the plurality of pads, and the second ring oscillator may output a test clock signal to a second pad among the plurality of pads.

According to some implementations, there is provided a semiconductor device including a lower semiconductor die including a lower element region including a plurality of lower elements disposed on a lower substrate, a lower interconnection region disposed on the lower element region, and a plurality of lower via structures passing through the lower substrate, and an upper semiconductor die including an upper element region including a plurality of upper elements disposed on an upper substrate, and an upper interconnection region disposed on the upper element region, the upper semiconductor die stacked on the lower semiconductor die in one direction. Some lower elements, among the plurality of lower elements, and some upper elements, among the plurality of upper elements, may provide a first ring oscillator outputting a reference clock signal generated from a signal transmission path including first via structures among the plurality of lower via structures, and a second ring oscillator outputting a test clock signal generated from a signal transmission path including second via structures different from the first via structures, among the plurality of via structures.

According to some implementations, there is provided a semiconductor device including a lower semiconductor die and an upper semiconductor die stacked on each other, the semiconductor device including a first ring oscillator including first lower unit circuits provided by some lower standard cells, among lower standard cells included in the lower semiconductor die, first upper unit circuits provided by some upper standard cells, among upper standard cells included in the upper semiconductor die, the first upper unit circuits alternately connected to the first lower unit circuits, and a first logic gate having a first input terminal receiving an enable signal and a second input terminal connected to one of the first lower unit circuits and the first upper unit circuits, and a second ring oscillator including second lower unit circuits provided by other some lower standard cells, among the lower standard cells, second upper unit circuits provided by other some upper standard cells, among the upper standard cells, the second upper unit circuits alternately connected to the second lower unit circuits, a second logic gate having a first input terminal receiving the enable signal and a second input terminal connected to one of the second lower unit circuits and the second upper unit circuits, and a test circuit delaying a raw clock signal input to the second input terminal of the second logic gate.

### BRIEF DESCRIPTION OF DRAWINGS

The above and other aspects, features, and advantages of implementations according to the present disclosure will be more clearly understood from the following detailed description, taken in conjunction with the accompanying drawings, in which:

FIG. 1 is a schematic diagram illustrating an example of a semiconductor device;

FIGS. 2A, 2B, and 3 are schematic diagrams illustrating examples of semiconductor devices;

FIGS. 4A and 4B are schematic circuit diagrams illustrating examples of ring oscillators;

FIGS. 5 and 6 are schematic diagrams illustrating an example of a semiconductor device;

FIG. 7 is a diagram illustrating an example of operation of a semiconductor device;

FIG. 8 is a schematic diagram illustrating an example of a semiconductor device;

FIG. 9 is a diagram illustrating an example of operation of a semiconductor device;

FIGS. 10 and 11 are schematic diagrams illustrating an example of a semiconductor device;

FIGS. 12 and 13 are schematic diagrams illustrating an example of a semiconductor device; and

FIGS. 14 to 16 are schematic diagrams illustrating an example of a semiconductor device.

### DETAILED DESCRIPTION

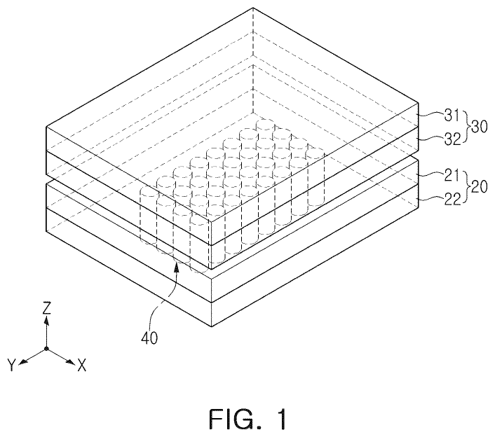

Referring to FIG. 1, a semiconductor device 10 includes a lower semiconductor die 20 and an upper semiconductor die 30. The lower semiconductor die 20 and the upper semiconductor die 30 may be stacked in a first direction (Z-axis direction). For example, the lower semiconductor die 20 and the upper semiconductor die 30 may be electrically connected to each other, and thus may operate while exchanging a clock signal and/or a data signal. In some implementations, the lower semiconductor die 20 and the upper semiconductor die 30 may provide a semiconductor chip performing various functions.

The lower semiconductor die 20 may include a first lower region 21 and a second lower region 22 including a lower substrate. The upper semiconductor die 30 may include a first upper region 31 and a second upper region 32 including an upper substrate. In the lower semiconductor die 20, the first lower region 21 may include a lower substrate, and a plurality of via structures 40 passing through the lower substrate, and the second lower region 22 may include a plurality of lower elements, interconnection patterns for connecting the plurality of lower elements, and insulating layers on which the interconnection patterns are disposed.

At least some lower elements, among the plurality of lower elements included in the lower semiconductor die 20, may include a plurality of lower standard cells arranged in a second direction (X-axis direction) and a third direction (Y-axis direction). Each of the plurality of lower standard cells may include a predefined logic circuit.

The first upper region 31 may include an upper substrate, and the second upper region 32 may include a plurality of upper elements, interconnection patterns for connecting the plurality of upper elements to each other, and insulating layers on which the interconnection patterns are disposed. The plurality of upper elements may include a plurality of upper standard cells arranged in the second and third directions, and each of the plurality of upper standard cells may include a predefined logic circuit. In the semiconductor device 10 illustrated in FIG. 1, the lower semiconductor die 20 and the upper semiconductor die 30 are stacked on each other, such that the first lower region 21 of the lower semiconductor die 20 and the second upper region 32 of the upper semiconductor die 30 are adjacent to each other.

Referring to FIG. 1, the lower semiconductor die 20 (in this example, unlike the upper semiconductor die 30) includes a plurality of via structures 40. Each of the plurality of via structures 40 may be a through-silicon via (TSV) passing through the lower substrate of the lower semiconductor die 20. The plurality of via structures 40 pass through the first lower region 21 and may optionally pass through the second lower region 22 in some implementations.

Surfaces of the plurality of via structures 40 may be exposed to the outside of the lower substrate included in the first lower region 21, and may be connected to pads formed on a surface of the second upper region 32. The surfaces of the plurality of via structures 40 may be connected to pads formed on a surface of the second lower region 22. Accordingly, the lower semiconductor die 20 and the upper semiconductor die 30 may be electrically connected to each other by the plurality of via structures 40.

As described above, while the semiconductor device 10 operates, the lower semiconductor die 20 and the upper semiconductor die 30 may operate by exchanging a clock signal and/or a data signal with each other. A transmission path for the clock signal and/or the data signal may be provided by the plurality of via structures 40, and an input/output circuit, transmitting or receiving a signal through the plurality of via structures 40, may be connected to the plurality of via structures 40. Accordingly, for stable operation of the semiconductor device 10, it may be useful to accurately determine delay characteristics between the lower semiconductor die 20 and the upper semiconductor die 30.

In some implementations, a ring oscillator transmitting a clock signal from the lower semiconductor die 20 and the upper semiconductor die 30 through at least some via structures, among the plurality of via structures 40, is included in the semiconductor device 10. The semiconductor device 10 may include a first ring oscillator generating a reference clock signal, and a second ring oscillator generating a test clock signal through a test cell or a test TSV on which measurement of delay characteristics is to be performed. A frequency difference and/or a phase difference between the reference clock signal and the test clock signal generated in the semiconductor device 10 may be detected to accurately measure signal delay characteristics of the test cell or the test TSV, thereby improving reliability of the semiconductor device 10 based thereon.

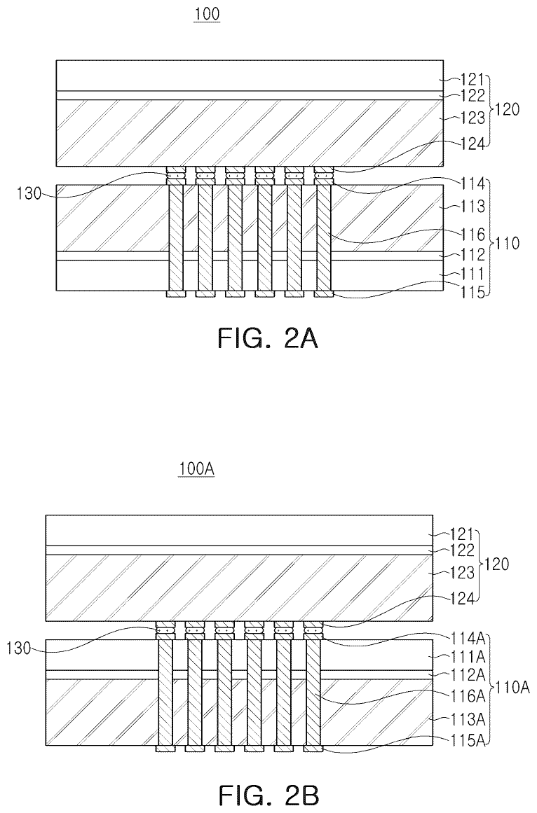

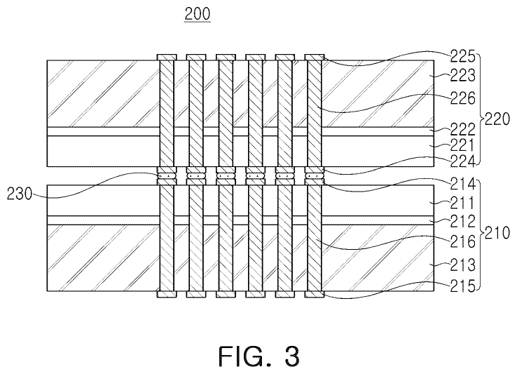

FIGS. 2A, 2B, and 3 are schematic diagrams illustrating examples of semiconductor devices according to some implementations.

First, referring to FIG. 2A, a semiconductor device 100 may include a lower semiconductor die 110 and an upper semiconductor die 120, stacked on each other. The lower semiconductor die 110 may include a lower substrate 111, a lower element region 112, a lower interconnection region 113, and the like, and the upper semiconductor die 120 may include an upper substrate 121, an upper element region 122, an upper interconnection region 123, and the like. A plurality of elements (e.g., circuit elements) may be disposed in each of the element regions 112 and 122, and interconnection patterns and insulating layers may be disposed in each of the interconnection regions 113 and 123.

The lower semiconductor die 110 may further include a plurality of via structures 116 passing through the lower substrate 111. Each of the plurality of via structures 116 may be a TSV passing through the lower substrate 111. In FIG. 2A, each of the plurality of via structures 116 is illustrated as passing through the lower substrate 111, the lower element region 112, and the lower interconnection region 113. However, in some implementations, the plurality of via structures 116 are formed to pass through the lower substrate 111 (e.g., without passing through the lower interconnection region 113) and are electrically connected to other via structures formed in the lower interconnection region 113. One surface (e.g., a top surface) of each of the plurality of via structures 116 may be connected to pads 114 exposed to the outside of the lower interconnection region 113, and the other surface (e.g., a bottom surface) of each of the plurality of via structures 116 may be connected to pads 115 formed on one surface of the lower substrate 111. In some implementations, the pads 115, exposed to the outside from the one surface of the lower substrate 111, are connected to an external circuit board.

The pads 114 may be electrically connected to pads 124, exposed to the outside of the upper interconnection region 123 of the upper semiconductor die 120 through a plurality of microbumps 130. Accordingly, the upper semiconductor die 120 and the lower semiconductor die 110 may be electrically connected to each other through the plurality of via structures 116, and a signal, input and output to the pads 115 through the external circuit board or the like, may be transmitted to the upper semiconductor die 120. The plurality of via structures 116 may provide a signal transmission path between the upper semiconductor die 120 and the lower semiconductor die 110.

As shown in FIG. 2A, the lower interconnection region 113 and the upper interconnection region 123 may be disposed between the lower element region 112 and the upper element region 122. In addition, the lower element region 112 and the upper element region 122 may be disposed between the lower substrate 111 and the upper substrate 121.

Referring to FIG. 2B, a semiconductor device 100A according to some implementations may include a lower semiconductor die 110A and an upper semiconductor die 120, stacked on each other. The lower semiconductor die 110A may include a lower substrate 111A, a lower element region 112A, a lower interconnection region 113A, and the like, and the upper semiconductor die 120 may include an upper substrate 121, an upper element region 122, an upper interconnection region 123, and the like.

The lower semiconductor die 110A may further include a plurality of via structures 116A. Each of the plurality of via structures 116A may be a TSV having a region passing through the lower substrate 111. One surface of each of the plurality of via structures 116A may be connected to pads 114A formed on one surface of the lower substrate 111A, and the other surface of each of the plurality of via structures 116A may be connected to pads 115A exposed to the outside of the lower interconnection region 113A. In some implementations, the pads 115A, exposed to the outside of the lower interconnection region 113A, are connected to an external circuit board.

The pads 114A may be electrically connected to pads 124, exposed to the outside of the upper interconnection region 123 of the upper semiconductor die 120, through a plurality of microbumps 130. Accordingly, the upper semiconductor die 120 and the lower semiconductor die 110A may be electrically connected to each other through the plurality of via structures 116A, and the plurality of via structures 116A may provide a signal transmission path between the upper semiconductor die 120 and the lower semiconductor die 110A.

As shown in FIG. 2B, the upper interconnection region 123 may be disposed between the lower element region 112A and the upper element region 122, and the lower interconnection region 113A may not be disposed between the lower element region 112A and the upper element region 122. For example, the lower element region 112A may be arranged between the lower interconnection region 113A and the upper element region 122. In addition, the lower substrate 111A may be disposed between the lower element region 112A and the upper interconnection region 123.

Referring to FIG. 3, a semiconductor device 200 according to some implementations includes a lower semiconductor die 210 and an upper semiconductor die 220, stacked on each other. As described above with reference to FIGS. 2A-2B, the lower semiconductor die 210 may include a lower substrate 211, a lower element region 212, a lower interconnection region 213, and the like, and the upper semiconductor die 220 may include an upper substrate. 221, an upper interconnection region 222, an upper interconnection region 223, and the like.

As shown in FIG. 3, the lower semiconductor die 210 may include a plurality of lower via structures 216, and the upper semiconductor die 220 may include a plurality of upper via structures 226. Each of the plurality of lower via structures 216 and the plurality of upper via structures 226 may be a TSV having a region passing through the substrates 211 and 221.

One surface of each of the plurality of lower via structures 216 may be connected to pads 214 formed on one surface of the lower substrate 211, and the other surface of each of the plurality of lower via structures 216 may be connected to pads 215 exposed to the outside of the lower interconnection region 213. One surface (e.g., a lower surface) of each of the plurality of upper via structures 226 may be connected to pads 224 formed on one surface of the upper substrate 221, and the other surface (e.g., an upper surface) of each of the plurality of upper via structures 226 may be connected to pads 225 exposed to the outside of the upper interconnection region 223. In some implementations, the pads 225, exposed to the outside of the upper interconnection region 223, may be omitted.

The pads 214, exposed externally from the one surface of the lower substrate 211, and the pads 224, exposed externally from the one surface of the upper substrate 221, may be connected to each other by a plurality of microbumps 230. Accordingly, the upper semiconductor die 220 and the lower semiconductor die 210 may be electrically connected to each other through the plurality of lower via structures 216 and the plurality of upper via structures 226. The plurality of lower via structures 216 and the plurality of upper via structures 226 may provide a signal transmission path between the upper semiconductor die 220 and the lower semiconductor die 210.

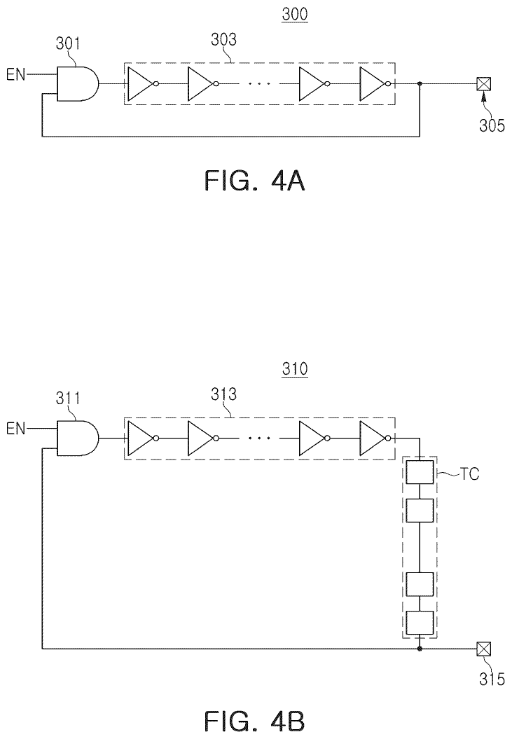

FIGS. 4A and 4B are schematic circuit diagrams illustrating a ring oscillator included in a semiconductor device according to some implementations.

A semiconductor device may include a first ring oscillator 300 generating a reference clock signal, and a second ring oscillator 310 generating a test clock signal having a frequency different from that of the reference clock signal. In some implementations, the test clock signal may have not only a frequency difference but also a phase difference from the reference clock signal. The second ring oscillator 310 may further include a test circuit connected to a front end of an output terminal of the first ring oscillator 300, and the frequency difference and/or the phase difference between the reference clock signal and the test clock signal may be generated by the test circuit.

Referring to FIG. 4A, the first ring oscillator 300 may include a first logic gate 301 and a first inverter circuit 303 in which a plurality of inverters are connected to each other. The inverters included in the first inverter circuit 303, may be connected to each other in series, and a number of the inverters included in the first inverter circuit 303 may be odd. Therefore, the first inverter circuit 303 may invert an output of the first logic gate 301 to generate an output signal, and the output signal may be an inverted signal of the output of the first logic gate 301. An output terminal of the first inverter circuit 303 may be connected to a first pad 305.

One input terminal, among input terminals of the first logic gate 301, may receive an enable signal EN, and the other input terminal may be connected to the output terminal of the first inverter circuit 303. When the enable signal EN is set to have a voltage level corresponding to a logic value of “1,” the output of the first logic gate 301 may be inverted by the first inverter circuit 303 and output to the first pad 305. In an initial state, when the first logic gate 301 outputs an output voltage corresponding to “0,” a voltage corresponding to “1” may be output to the first pad 305.

A voltage of the first pad 305 may be fed back to the first logic gate 301, such that the output voltage of the first logic gate 301 may be adjusted to a voltage level corresponding to “1.” Using such a process, a reference clock signal having a predetermined frequency may be output to the first pad 305. A period of the reference clock signal may be determined by the number of the plurality of inverters included in the first inverter circuit 303 and/or by RC characteristics of each of the plurality of inverters.

Referring to FIG. 4B, the second ring oscillator 310 may include a second logic gate 311, a second inverter circuit 313, and a test circuit TC. The second inverter circuit 313 may include a plurality of inverters connected to each other in series, and a number of the inverters included in the second inverter circuit 313 may be odd. Therefore, the second inverter circuit 313 may to invert an output of the second logic gate 311 to generate an output signal, and the output signal may be an inverted signal of the output of the second logic gate 311. The number of inverters included in the second inverter circuit 313 may be equal to the number of inverters included in the first inverter circuit 303. An output terminal of the second inverter circuit 313 may be connected to a second pad 315.

One input terminal, among input terminals of the second logic gate 311, may receive an enable signal EN, and the other input terminal may be connected to the output terminal of the second inverter circuit 313. The first logic gate 301 and the second logic gate 311 may receive the same enable signal EN. An operation of the second ring oscillator 310 may be similar to an operation of the first ring oscillator 300. When the enable signal EN is set to have a voltage level corresponding to a logic value of “1,” the output of the second logic gate 311 may be inverted by the second inverter circuit 313 and input to the test circuit TC.

The test circuit TC may include a plurality of test cells connected to each other in series. Each of the plurality of test cells may include a single circuit, and the plurality of test cells may include the same circuit. The test circuit TC may be configured to not invert an output voltage of the second inverter circuit 313.

A signal generated by the second logic gate 311 and the second inverter circuit 313 may be the same as the reference clock signal, output by the first ring oscillator 300 to the first pad 305. A test clock signal, having a frequency and/or a phase obtained by changing a frequency and/or a phase of the reference clock signal, may be output to the second pad 315 by the test circuit TC. A frequency difference and/or a phase difference between the test clock signal and the reference clock signal may be determined by the number of the test cells included in the test circuit TC and/or characteristics of each of the test cells.

For example, the reference clock signal is measured at the first pad 305 of the semiconductor device and the test clock signal is measured at the second pad 315 of the semiconductor device, and the frequency difference and/or the phase difference between the reference clock signal and the test clock signal may be calculated. For example, a difference between a single period of the reference clock signal and a single period of the test clock signal may be detected, and the difference may be divided by the number of the test cells included in the test circuit TC, thereby determining signal delay characteristics of an individual test cell.

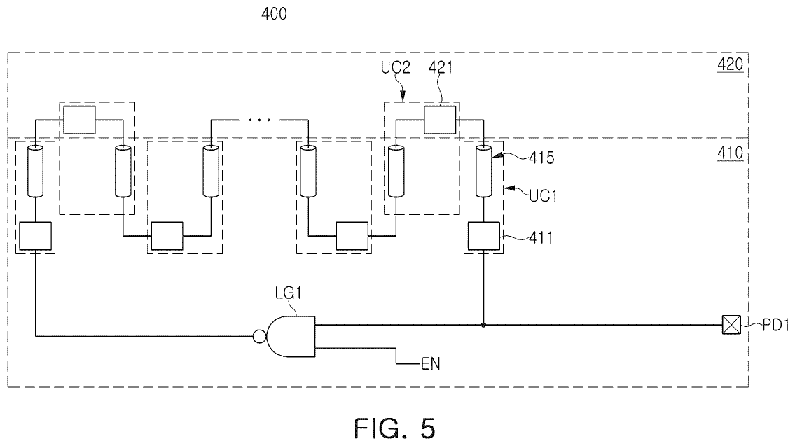

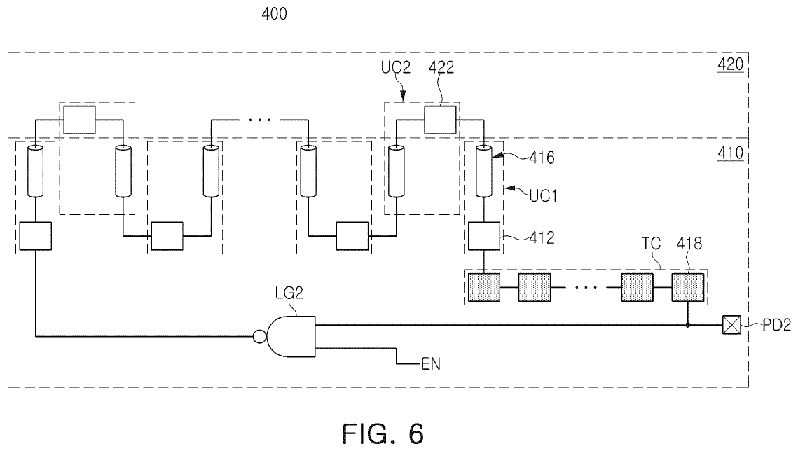

Referring to FIGS. 5 and 6, a semiconductor device 400 according to some implementations includes a lower semiconductor die 410 and an upper semiconductor die 420. Each of the lower semiconductor die 410 and the upper semiconductor die 420 may include a substrate, an element region, and an interconnection region, and a plurality of standard cells may be provided by a plurality of elements disposed in the element region and at least one interconnection pattern, among interconnection patterns disposed in the interconnection region.

Some lower standard cells, among a plurality of lower standard cells included in the lower semiconductor die 410, may be connected to some upper standard cells, among a plurality of upper standard cells included in the upper semiconductor die 420, through via structures 415 passing through a lower substrate. Accordingly, the lower semiconductor die 410 and the upper semiconductor die 420 may operate while exchanging a signal with each other.

Referring to FIG. 5, the first ring oscillator may include a first logic gate LG1, a plurality of first lower reference cells 411, a plurality of first upper reference cells 421, and a plurality of first via structures 415. The first logic gate LG1 is illustrated as a NAND gate, but may be implemented as an AND gate, NOR gate, or the like. The first logic gate LG1 may be provided by at least one of the plurality of lower standard cells.

The plurality of first lower reference cells 411 may be some lower standard cells, among the lower standard cells included in the lower semiconductor die 410, and the plurality of first upper reference cells 421 may be some upper standard cells, among the upper standard cells included in the upper semiconductor die 420. In some implementations, each of the plurality of first lower reference cells 411 and the plurality of first upper reference cells 421 may include elements manufactured using semiconductor processes having different scales. For example, an individual element, included in each of the plurality of first lower reference cells 411, may be manufactured using a 5 nm process, and an individual element, included in each of the plurality of first upper reference cells 421, may be manufactured using a 3 nm process.

The plurality of first lower reference cells 411 may provide a plurality of first unit circuits UC1, together with some first via structures among the plurality of first via structures 415. The plurality of first upper reference cells 421 may provide a plurality of second unit circuits UC2, together with other first via structures among the plurality of first via structures 415. Each of the plurality of first lower reference cells 411 and the plurality of first upper reference cells 421 may provide a circuit inputting and outputting a signal through the plurality of first via structures 415.

As illustrated in FIG. 5, the plurality of first lower reference cells 411 and the plurality of first upper reference cells 421 may be connected to each other in series, and may be alternately disposed. The number and types of the plurality of first lower reference cells 411 and the plurality of first upper reference cells 421 may vary depending on the first logic gate LG1. In a case in which the first logic gate LG1 is a NAND gate, as in the example of FIG. 5, each of the plurality of first lower reference cells 411 and the plurality of first upper reference cells 421 may be implemented as a non-inverting cell outputting an output signal without inverting an input signal. For example, each of the plurality of first lower reference cells 411 and the plurality of first upper reference cells 421 may include a buffer, a delay circuit, or the like.

One of the input terminals of the first logic gate LG1 may receive an enable signal EN, and another one may be connected to a first pad PD1, an output terminal of the first ring oscillator. When the enable signal EN is set to have a voltage level corresponding to a logic value of “1,” the first logic gate LG1 may invert a voltage of the first pad PD1 and output the inverted voltage. Accordingly, each of the plurality of first lower reference cells 411 and the plurality of first upper reference cells 421 may be configured as a non-inverting cell, such that a reference clock signal having a predetermined frequency may be output from the first pad PAD1.

In a case in which the first logic gate LG1 is a logic gate not inverting the voltage of the first pad PD1, configurations of the plurality of first lower reference cells 411 and the plurality of first upper reference cells 421 may vary. For example, in a case in which the first logic gate LG1 is an AND gate, when the enable signal EN is set to have the voltage level corresponding to the logic value of “1,” the first logic gate LG1 may output the voltage of first pad PD1 without change.

Accordingly, in a case in which the first logic gate LG1 is an AND gate, the plurality of first lower reference cells 411 and the plurality of first upper reference cells 421 may invert an output voltage of the first logic gate LG1 and apply the inverted output voltage to the first pad PD1, such that the first pad PD1 may output a reference clock signal having a predetermined frequency. The output voltage of the first logic gate LG1 may be inverted in the upper reference cells 421 and applied to the first pad PD1. In this case, each of the plurality of first lower reference cells 411 and the plurality of first upper reference cells 421 may include an inverter. For example, each of the plurality of first lower reference cells 411 and the plurality of first upper reference cells 421 may be configured as an inversion cell inverting an input signal to output an output signal, and the total number of the plurality of first lower reference cells 411 and the plurality of first upper reference cells 421 may be odd. In a case in which the first logic gate LG1 is a NOR gate, when the enable signal EN has a voltage level corresponding to “0,” the first ring oscillator may transmit the reference clock signal to the first pad PD1.

Referring to FIG. 6, the second ring oscillator may include a second logic gate LG2, a plurality of second lower reference cells 412, a plurality of second upper reference cells 422, and a plurality of second via structures 416. The second logic gate LG2 is illustrated as a NAND gate, but may be implemented as an AND gate, NOR gate, or the like, and may be implemented as a logic gate the same as the first logic gate LG1. The second logic gate LG2 may be provided by at least one of the plurality of lower standard cells.

The plurality of second lower reference cells 412 may be some lower standard cells, among the lower standard cells included in the lower semiconductor die 410, and the plurality of second upper reference cells 422 may be some upper standard cells, among the upper standard cells included in the upper semiconductor die 420. In some implementations, each of the plurality of second lower reference cells 412 and the plurality of second upper reference cells 422 may include elements manufactured using semiconductor processes having different scales.

The plurality of second lower reference cells 412 may provide a plurality of first unit circuits UC1, together with some second via structures among the plurality of second via structures 416. The plurality of second upper reference cells 422 may provide a plurality of second unit circuits UC2, together with other second via structures among the plurality of second via structures 416. Each of the plurality of second lower reference cells 412 and the plurality of second upper reference cells 422 may provide a circuit capable of transmitting and receiving a signal through the plurality of second via structures 416.

The plurality of second lower reference cells 412 and the plurality of second upper reference cells 422 may be connected to each other in series, and may be alternately disposed. The number and types of the plurality of second lower reference cells 412 may be the same as the number and types of the plurality of first lower reference cells 411 included in the first ring oscillator. In addition, the number and types of the plurality of second upper reference cells 422 may be the same as the number and types of the plurality of first upper reference cells 421 included in the first ring oscillator. Accordingly, a clock signal, the same as the reference clock signal output by the first ring oscillator to the first pad PD1, may be output by a first unit circuit UC1, disposed at a rearmost end, along a transmission path of an output signal of the second logic gate LG2.

However, the second ring oscillator may further include a test circuit TC connected to a node between an input terminal of the second logic gate LG2 and a second pad PD2, and connected between the first unit circuit UC1 and the second pad PD2 and the second logic gate LG2. The test circuit TC may include test cells 418 that are some lower standard cells, among the plurality of lower standard cells included in the lower semiconductor die 410. The test cells 418 may be connected to each other in series, and a frequency and a phase of a first test clock signal, output to the second pad PD2, may be determined depending on characteristics of a logic circuit provided by each of the test cells 418 and the number of test cells 418.

For example, the test circuit TC may be configured to output an output signal without inverting an input signal. A frequency difference and/or a phase difference between the first test clock signal, output to the second pad PD2, and the reference clock signal, output to the first pad PD1, may be determined by delay characteristics of the test circuit TC.

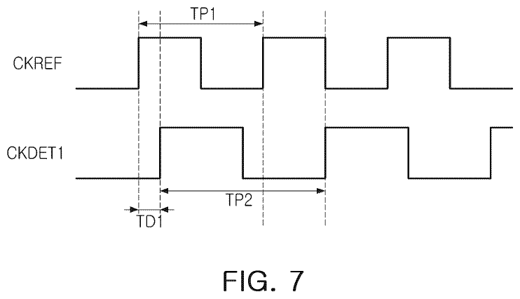

FIG. 7 illustrates an example of a reference clock signal CKREF, output to the first pad PD1, and a first test clock signal CKDET1, output to the second pad PD2. In the example of FIG. 7, the reference clock signal CKREF has a first period TP1, and the first test clock signal CKDET1 has a second period TP2 longer than the first period TP1. In addition, the first test clock signal CKDET1 has a phase that is late by a first delay time TD1.

The reference clock signal CKREF may be measured at the first pad PD1, and the first test clock signal CKDET1 may be measured at the second pad PD2, to calculate a difference between the first period TP1 and the second period TP2, thereby determining delay characteristics of the test cells 418. For example, the difference between the first period TP1 and the second period TP2 may be divided by the number of test cells 418, thereby determining signal delay characteristics of an individual test cell 418.

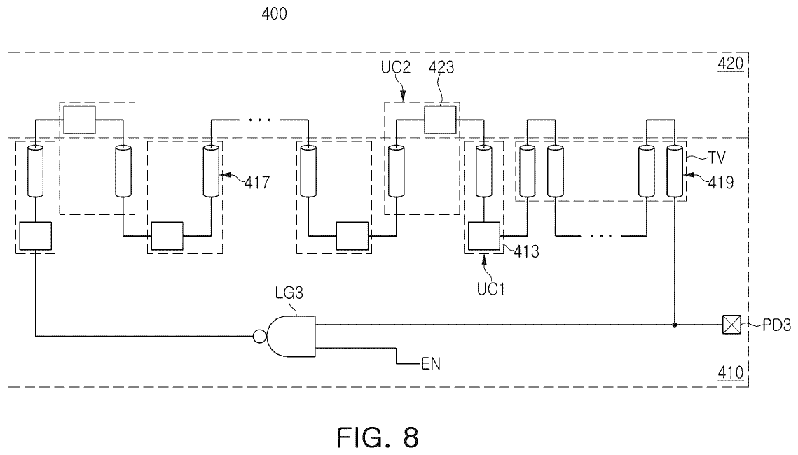

Referring to FIG. 8, a semiconductor device 400 according to some implementations of the present disclosure may include a third ring oscillator. The third ring oscillator may be included in a single semiconductor device 400, together with the first ring oscillator and the second ring oscillator described above with reference to FIGS. 5 and 6. However, in some implementations, the single semiconductor device 400 may include only the first ring oscillator and the second ring oscillator, or only the first ring oscillator and the third ring oscillator.

The third ring oscillator includes a third logic gate LG3, a plurality of third lower reference cells 413, a plurality of third upper reference cells 423, and a plurality of third via structures 417. In the same manner as the second ring oscillator described above with reference to FIG. 6, the third logic gate LG3 may include a logic gate that is the same as the first logic gate LG1 of the first ring oscillator, and that may be provided by at least one of a plurality of lower standard cells. In addition, the number of the plurality of third lower reference cells 413 may be the same as the number of the plurality of first lower reference cells 411, and a logic circuit provided by each of the plurality of third lower reference cells 413, may be the same as a logic circuit provided by each of the plurality of first lower reference cells 411.

The number of the plurality of third upper reference cells 423 may be the same as the number of the plurality of first upper reference cells 421, and a logic circuit provided by each of the plurality of third upper reference cells 423 may be the same as a logic circuit provided by each of the plurality of first upper reference cells 421. Accordingly, a clock signal, the same as the reference clock signal output by the first ring oscillator to the first pad PD1, may be output by a first unit circuit UC1, disposed at a rearmost end, along a transmission path of an output signal of the third logic gate LG3.

As illustrated in FIG. 8, the third ring oscillator may further include a test circuit TV connected between an input terminal of the third logic gate LG3 and a third pad PD3. The test circuit TV, included in the third ring oscillator, may include two or more test via structures 419 electrically connecting the lower semiconductor die 410 and the upper semiconductor die 420 to each other. The test via structures 419 may be connected to each other in series without an input/output circuit. Accordingly, a frequency and/or a phase of a second test clock signal, output to the third pad PD3, may be determined depending on characteristics of each of the test via structures 419 and the number of test via structures 419.

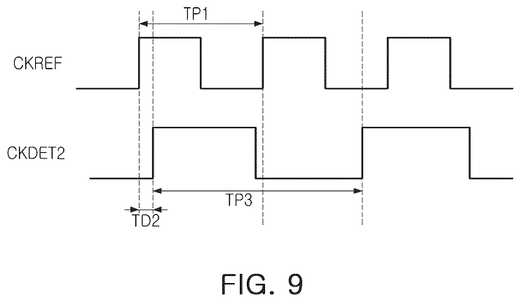

FIG. 9 illustrates an example of the reference clock signal CKREF, output to the first pad PD1, and a second test clock signal CKDET2, output to the third pad PD3. In the example of FIG. 8, the test circuit TV may include only test via structures 419 connected to each other without a logic circuit for processing a signal, such that, in some cases, a frequency of the second test clock signal CKDET2 may be the same as that of the reference clock signal CKREF generated by the first ring oscillator.

Referring to FIG. 9, the second test clock signal CKDET2 may have a third period TP3 different from the first period TP1 of the reference clock signal CKREF. In addition, or instead, the second test clock signal CKDET2 may have a phase that is late by a second delay time TD2, as compared to the reference clock signal CKREF. A difference between the first period TP1 of the reference clock signal CKREF, measured at the first pad PD1, and the third period TP3 of the second test clock signal CKDET2, measured at the third pad PD3, may be calculated, thereby determining delay characteristics of the test via structures 419. For example, the difference between the first period TP1 and the third period TP3 may be divided by the number of the test via structures 419, thereby determining signal delay characteristics of an individual via structure included in the semiconductor device 400.

As described with reference to FIGS. 5 to 9, a semiconductor device (e.g., semiconductor device 400) may include the first ring oscillator generating the reference clock signal CKREF, and the second ring oscillator and/or the third ring oscillator including the test circuits TC and TV on which measurement of signal delay characteristics is to be performed. The test circuit TC may be configured to include test cells 418 on which measurement of signal delay characteristics is to be performed, and a frequency and/or a phase of the test clock signal CKDET1, output through the test circuit TC, may be compared to a frequency and/or a phase of the reference clock signal CKREF to determine signal delay characteristics of the test cells 418. In addition, the test circuit TV may be configured to include test via structures 419, and a frequency and/or a phase of the test clock signal CKDET2, output through the test circuit TV, may be compared to the frequency and/or the phase of the reference clock signal CKREF to determine signal delay characteristics of the test via structures 419.

In some implementations, signal delay characteristics, appearing in one of the lower semiconductor die 410 and the upper semiconductor die 420, may be compared to signal delay characteristics, appearing between the lower semiconductor die 410 and the upper semiconductor die 420, thereby analyzing signal delay characteristics of the semiconductor device 400 having a three-dimensional structure. For example, each of a reference ring oscillator, generating a reference clock signal, and a test ring oscillator, generating a test clock signal, may be implemented with only standard cells included in the lower semiconductor die 410, and the test ring oscillator may be implemented to include the test circuit TC including the test cells 418.

Frequencies and/or phases of a reference clock signal and a test clock signal, respectively output by a reference ring oscillator and a test ring oscillator implemented solely in the lower semiconductor die 410, may be compared to each other to analyze signal delay characteristics of the test cells 418. In addition, signal delay characteristics of the test cells 418, analyzed using the reference ring oscillator and the test ring oscillator of the lower semiconductor die 410, may be compared to signal delay characteristics of the test cells 418, analyzed using the first ring oscillator and the second ring oscillator described above with reference to FIGS. 5 and 6, thereby determining an effect of the three-dimensional structure of the semiconductor device 400 on signal delay characteristics.

In the examples described with reference to FIGS. 5 to 9, it is illustrated that the logic gates LG1, LG2, and LG3 for implementing a ring oscillator are included in the lower semiconductor die 410, together with the pads PD1, PD2, and PD3 to which the ring oscillator outputs a clock signal, but the arrangements of circuit elements are not limited thereto. For example, the logic gates LG1, LG2, and LG3 may be included in the upper semiconductor die 420, and the pads PD1, PD2, and PD3 for outputting the clock signal may be included in the lower semiconductor die 410. In this case, a path, connecting input terminals of the logic gates LG1, LG2, and LG3 to the pads PD1, PD2, and PD3, may include a via structure.

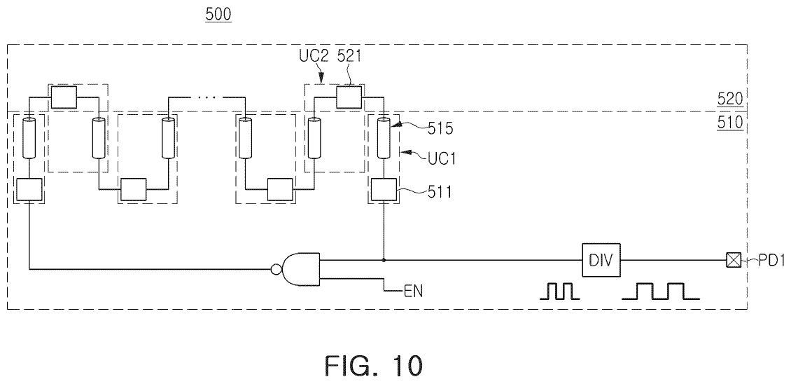

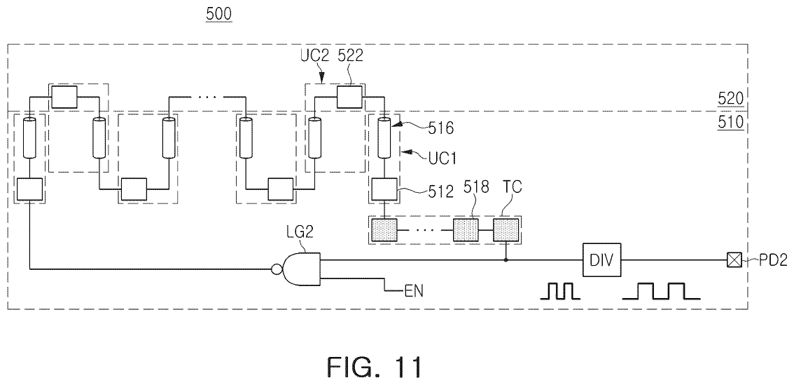

Referring to FIGS. 10 and 11, a semiconductor device 500 may include a lower semiconductor die 510 and an upper semiconductor die 520. Each of the lower semiconductor die 510 and the upper semiconductor die 520 may include a substrate, an element region, and an interconnection region. A plurality of standard cells may be provided by a plurality of elements disposed in the element region and some interconnection patterns, among interconnection patterns disposed in the interconnection region. Some lower standard cells, among a plurality of lower standard cells disposed in the lower semiconductor die 510, may be connected to some upper standard cells, among a plurality of upper standard cells disposed in the upper semiconductor die 520, through via structures 515 passing through a substrate of the lower semiconductor die 510.

FIG. 10 illustrates an example of a first ring oscillator included in the semiconductor device 500. Referring to FIG. 10, the first ring oscillator may include a first logic gate LG1, a plurality of first lower reference cells 511, a plurality of first upper reference cells 521, and a plurality of first via structures 515. The first logic gate LG1 is illustrated as a NAND gate, but may also be implemented as an AND gate, NOR gate, or the like.

The plurality of first lower reference cells 511 may be some lower standard cells, among the lower standard cells included in the lower semiconductor die 510, and the plurality of first upper reference cells 521 may be some upper standard cells, among the upper standard cells included in the upper semiconductor die 520. In some implementations, each of the plurality of first lower reference cells 511 and the plurality of first upper reference cells 521 may include elements manufactured using semiconductor processes having different scales.

The plurality of first lower reference cells 511 may provide a plurality of first unit circuits UC1, together with some first via structures among the plurality of first via structures 515. The plurality of first upper reference cells 521 may provide a plurality of second unit circuits UC2, together with other first via structures among the plurality of first via structures 515. In some implementations, each of the plurality of first lower reference cells 511 and the plurality of first upper reference cells 521 provides a circuit capable of transmitting and receiving a signal through the plurality of first via structures 515.

One of input terminals of the first logic gate LG1 may receive an enable signal EN, and another one may be connected to a first pad PD1, an output terminal of the first ring oscillator. When the enable signal EN is set to have a voltage level corresponding to a logic value of “1,” the first logic gate LG1 may invert a voltage of the first pad PD1 and output the inverted voltage. Each of the plurality of first lower reference cells 511 and the plurality of first upper reference cells 521 may provide a logic circuit not inverting a phase of an input signal, such that the first pad PD1 may output a reference clock signal having a predetermined frequency. However, in a case in which the first logic gate LG1 is a logic gate not inverting the voltage of the first pad PD1, for example, an AND gate, each of the plurality of first lower reference cells 511 and the plurality of first upper reference cells 521 may provide a logic circuit inverting a phase of an input signal. In this case, the total number of the plurality of first unit circuits UC1 and the plurality of second unit circuits UC2 may be odd.

FIG. 11 illustrates an example of a second ring oscillator included in the semiconductor device 500. Referring to FIG. 11, the second ring oscillator may include a second logic gate LG2, a plurality of second lower reference cells 512, a plurality of second upper reference cells 522, and a plurality of second via structures 516. The second logic gate LG2 may be implemented as a logic gate the same as the first logic gate LG1.

The plurality of second lower reference cells 512 may provide a plurality of first unit circuits UC1, together with some second via structures among the plurality of second via structures 516. The plurality of second upper reference cells 522 may provide a plurality of second unit circuits UC2, together with other second via structures among the plurality of second via structures 516. Each of the plurality of second lower reference cells 512 and the plurality of second upper reference cells 522 may provide a circuit capable of exchanging and receiving a signal through the plurality of second via structures 516.

The number and types of the plurality of second lower reference cells 512 may be the same as the number and types of the plurality of first lower reference cells 511 included in the first ring oscillator. In addition, the number and types of the plurality of second upper reference cells 522 may be the same as the number and types of the plurality of first upper reference cells 521 included in the first ring oscillator. Accordingly, a clock signal, the same as the reference clock signal output by the first ring oscillator to the first pad PD1, may be output by a first unit circuit UC1, disposed at a rearmost end, along a transmission path of an output signal of the second logic gate LG2.

However, the second ring oscillator may further include a test circuit TC connected between an input terminal of the second logic gate LG2 and a second pad PD2. The test circuit TC may include test cells 518 that are some lower standard cells among the plurality of lower standard cells included in the lower semiconductor die 510. The test cells 518 may be connected to each other in series, and a frequency and a phase of a first test clock signal, output to the second pad PD2, may be determined depending on characteristics of a logic circuit provided by each of the test cells 518 and the number of test cells 518.

The test circuit TC may be configured to output an output signal without inverting an input signal or changing a frequency of the input signal. Accordingly, a signal, output to the second pad PD2 may have a frequency the same as that of a signal output to the first pad PD1.

Referring to FIGS. 10 and 11, each of the first ring oscillator and the second ring oscillator may include a divider DIV. In the first ring oscillator, the divider DIV may be connected to a front end of the first pad PD1. In the second ring oscillator, the divider DIV may be connected to a front end of the second pad PD2. Using the first ring oscillator as an example, the divider DIV may output a reference clock signal by lowering a frequency of a raw clock signal generated by the first logic gate LG1, the plurality of first unit circuits UC1, and the plurality of second unit circuits UC2. For example, the divider DIV may include a plurality of flip-flops connected to each other in series.

For example, when the frequency of the raw clock signal, generated by the first logic gate LG1, the plurality of first unit circuits UC1, and the plurality of second unit circuits UC2, is excessively high, it may be difficult to accurately detect the raw clock signal from the first pad PD1. As illustrated in FIGS. 10 and 11, a frequency of a clock signal may be lowered by connecting the divider DIV to front ends of the pads PD1 and PD2 in the first and second ring oscillators.

As described above, a frequency of a clock signal, generated by a ring oscillator, may vary depending on the number of unit circuits UC1 and UC2 connected to logic gates LG1 and LG2 in the ring oscillator. For example, as the number of the unit circuits UC1 and UC2 increases, a period of the clock signal may increase, and the frequency of the clock signal may be lowered. As illustrated in FIGS. 10 and 11, a frequency of a clock signal, generated by the unit circuits UC1 and UC2, may be lowered using the divider DIV. Accordingly, in order to implement the ring oscillator, the number of the unit circuits UC1 and UC2, connected to the logic gates LG1 and LG2, may be reduced.

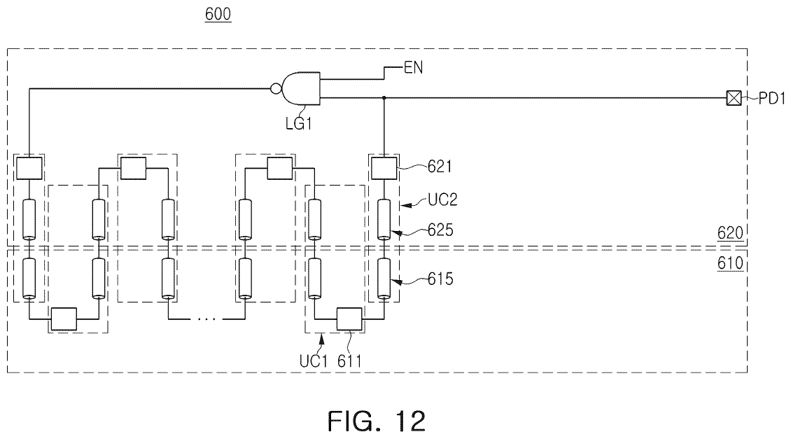

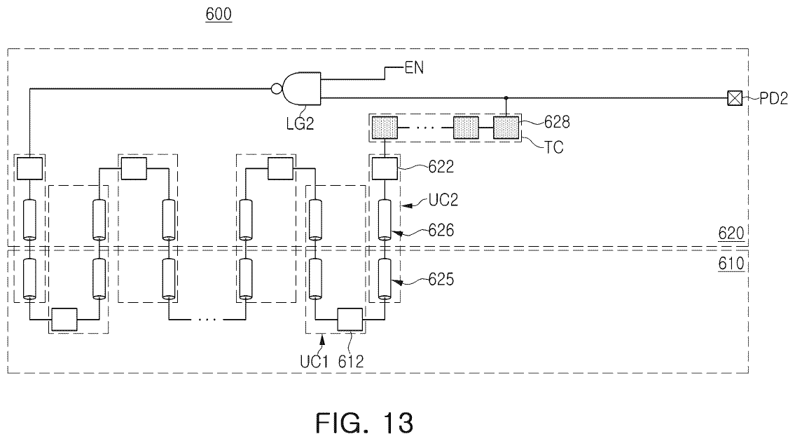

Referring to FIGS. 12 and 13, a semiconductor device 600 may include a lower semiconductor die 610 and an upper semiconductor die 620, stacked on each other in one direction. As shown in FIGS. 12 and 13, the lower semiconductor die 610 and the upper semiconductor die 620 may be stacked such that a lower substrate of the lower semiconductor die 610 and an upper substrate of the upper semiconductor die 620 are adjacent to each other in the one direction.

For example, the semiconductor device 600 may have a structure similar to that in the example described above with reference to FIG. 3. Accordingly, as illustrated in FIGS. 12 and 13, the lower semiconductor die 610 may include a plurality of lower via structures, and the upper semiconductor die 620 may include a plurality of upper via structures. The plurality of lower via structures and the plurality of upper via structures may be connected to each other to form a signal transmission path between the lower semiconductor die 610 and the upper semiconductor die 620.

FIG. 12 illustrates a structure of a first ring oscillator included in the semiconductor device 600, the first ring oscillator outputting a reference clock signal to a first pad PD1. Referring to FIG. 12, the first ring oscillator may include a first logic gate LG1, a plurality of first lower reference cells 611, a plurality of first upper reference cells 621, and a plurality of first lower via structures 615, and a plurality of second upper via structures 625. The first logic gate LG1 is illustrated as a NAND gate, but may be implemented as an AND gate, NOR gate, or the like.

The plurality of first lower reference cells 611 may be some lower standard cells, among lower standard cells included in the lower semiconductor die 610, and the plurality of first upper reference cells 621 may be some upper standard cells, among upper standard cells included in the upper semiconductor die 620. In some implementations, each of the plurality of first lower reference cells 611 and the plurality of first upper reference cells 621 may include elements manufactured using semiconductor processes having different scales.

The plurality of first lower reference cells 611 may provide a plurality of first unit circuits UC1, together with some via structures among the plurality of first lower via structures 615 and the plurality of second upper via structures 625. The plurality of first upper reference cells 621 may provide a plurality of second unit circuits UC2, together with other via structures among the plurality of first lower via structures 615 and the plurality of second upper via structures 625. The plurality of first unit circuits UC1 and the plurality of second unit circuits UC2 may be alternately disposed and connected to each other in series.

As illustrated in FIG. 12, the first logic gate LG1 and the first pad PD1 may be included in the upper semiconductor die 620. The first pad PD1 may be exposed externally from an interconnection region of the upper semiconductor die 620. Accordingly, a reference clock signal, generated by the first ring oscillator, may be detected by performing a probing operation on the first pad PD1. An operation of the first ring oscillator generating a reference clock signal may be understood with reference to the above-described examples.

FIG. 13 illustrates a structure of a second ring oscillator included in the semiconductor device 600, the second ring oscillator outputting a test clock signal to a second pad PD2. Referring to FIG. 13, the second ring oscillator may include a second logic gate LG2, a plurality of second lower reference cells 612, a plurality of second upper reference cells 622, a plurality of second lower via structures 616, and a plurality of second upper via structures 626.

The plurality of second lower reference cells 612 may be some lower standard cells, among the lower standard cells included in the lower semiconductor die 610, and the plurality of second upper reference cells 622 may be some upper standard cells, among the upper standard cells included in the upper semiconductor die 620. The number of the plurality of second lower reference cells 612 may be the same as the number of the plurality of first lower reference cells 611, and a logic circuit provided by each of the plurality of second lower reference cells 612, may be the same as a logic circuit provided by each of the plurality of first lower reference cells 611. The number of the plurality of second upper reference cells 622 may be the same as the number of the plurality of first upper reference cells 621, and a logic circuit provided by each of the plurality of second upper reference cells 622 may be the same as a logic circuit provided by each of the plurality of first upper reference cells 621.

Accordingly, a clock signal, input to a test circuit TC, may have a frequency the same as that of a reference clock signal, output by the first ring oscillator. The test circuit TC may include a plurality of test cells 628 connected to each other in series, and the plurality of test cells 628 may be some upper standard cells, among the upper standard cells included in the upper semiconductor die 620. A frequency and a phase of a test clock signal, output to the second pad PD2, may be determined depending on the number of the plurality of test cells 628 and signal delay characteristics appearing in a logic circuit provided by each of the plurality of test cells 628.

For example, the reference clock signal is measured at the first pad PD1 of the semiconductor device, the test clock signal is measured at the second pad PD2 of the semiconductor device, and a period difference between the reference clock signal and the test clock signal may be calculated. For example, the period difference between the reference clock signal and the test clock signal may be divided by the number of the test cells 628, thereby determining signal delay characteristics of a logic circuit implemented as a single test cell 308.

In the example described with reference to FIGS. 12 and 13, in some implementations, the pads PD1 and PD2 for detecting a clock signal may be provided in the lower semiconductor die 610, unlike the logic gates LG1 and LG2 which in this example are provided in the upper semiconductor die 620. For example, an input terminal to which a clock signal is fed back, among input terminals of the logic gates LG1 and LG2, may be connected to a via structure, and thus electrically connected to the pads PD1 and PD2 provided in the lower semiconductor die 610.

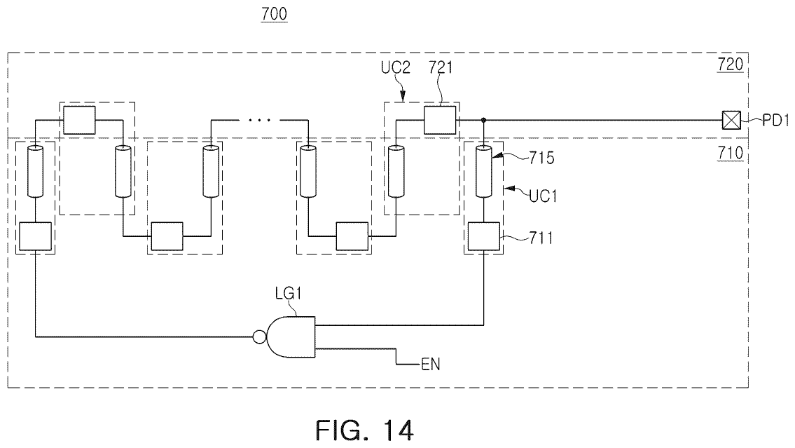

Referring to FIGS. 14 to 16, a semiconductor device 700 includes a lower semiconductor die 710 and an upper semiconductor die 720, stacked on each other in one direction. In the example described with reference to FIGS. 14 to 16, logic gates LG1, LG2, and LG3 for implementing ring oscillators and pads PD1, PD2, and PD3 for detecting clock signals generated by the ring oscillators are included in different semiconductor dies 710 and 720.

FIG. 14 illustrates a first ring oscillator included in the semiconductor device 700, the first ring oscillator outputting a reference clock signal to a first pad PD1. Referring to FIG. 14, the first ring oscillator may include a first logic gate LG1, a plurality of first lower reference cells 711, a plurality of first upper reference cells 721, a plurality of first via structures 715, and the like. An enable signal EN may be input to a first input terminal of the first logic gate LG1, and a raw clock signal may fed back to a second input terminal of the first logic gate LG1.

The plurality of first lower reference cells 711 may be some lower standard cells, among lower standard cells included in the lower semiconductor die 710, and the plurality of first upper reference cells 721 may be some upper standard cells, among upper standard cells included in the upper semiconductor die 720. In some implementations, each of the plurality of first lower reference cells 711 and the plurality of first upper reference cells 721 may include elements manufactured using semiconductor processes having different scales. At least one of a plurality of upper standard cells may provide the first logic gate LG1.

The plurality of first lower reference cells 711 provide a plurality of first unit circuits UC1, together with some via structures among a plurality of first lower via structures 715. The plurality of first upper reference cells 721 may provide a plurality of second unit circuits UC2, together with the other via structures among the plurality of first lower via structures 715. The plurality of first unit circuits UC1 and the plurality of second unit circuits UC2 may be alternately disposed and connected to each other in series.

As shown in FIG. 14, the first pad PD1 may be connected to a node between the first unit circuit UC1 and the second unit circuit UC2 sequentially connected from (e.g., closest to) an input terminal of the first logic gate LG1. Accordingly, the reference clock signal may be output to the first pad PD1 without passing through a via structure other than the plurality of first via structures 715 included in the first ring oscillator.

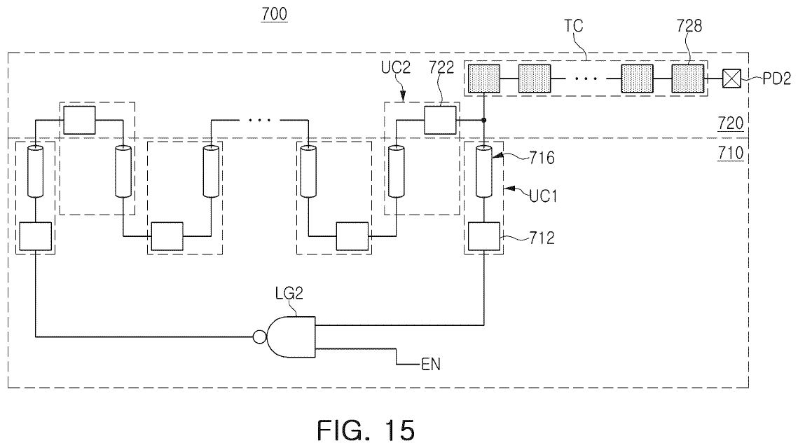

FIG. 15 illustrates a second ring oscillator included in the semiconductor device 700, the second ring oscillator outputting a first test clock signal to a second pad PD2. Referring to FIG. 15, the second ring oscillator may include a second logic gate LG2, a plurality of second lower reference cells 712, a plurality of second upper reference cells 722, a plurality of second via structures 716, and the like. An enable signal EN may be input to a first input terminal of the second logic gate LG2, and a raw clock signal may be fed back to a second input terminal of the second logic gate LG2.

The number of the plurality of second lower reference cells 712 may be the same as the number of the plurality of first lower reference cells 711, and a logic circuit, provided by each of the plurality of second lower reference cells 712, may be the same as a logic circuit, provided by each of the plurality of first lower reference cells 711. The number of the plurality of second upper reference cells 722 may be the same as the number of the plurality of first upper reference cells 721, and a logic circuit provided by each of the plurality of second upper reference cells 722 may be the same as a logic circuit provided by each of the plurality of first upper reference cells 721. At least one of the plurality of upper standard cells may provide the second logic gate LG2.

Accordingly, the raw clock signal, fed back to the second input terminal of the first logic gate LG1, may be the same as the raw clock signal, fed back to the second input terminal of the second logic gate LG2. In addition, in the second ring oscillator, a clock signal, transmitted to a test circuit connected to a node between the first unit circuit UC1 and the second unit circuit UC2 sequentially connected to the second input terminal, may be a signal substantially the same as the reference clock signal, output by the first ring oscillator to the first pad PD1.

Accordingly, the first test clock signal, output to the second pad PD2, may have a frequency difference and/or a phase difference from the reference clock signal, output to the first pad PD1. The frequency difference and/or phase difference between the reference clock signal and the first test clock signal may be determined by a test circuit TC. For example, a difference between a period of the reference clock signal and a period of the first test clock signal may be determined depending on the number of test cells 728 included in the test circuit TC and signal delay characteristics of a logic circuit provided by an individual test cell 728. Accordingly, the period difference between the reference clock signal and the first test clock signal may be divided by the number of test cells 728, thereby determining the signal delay characteristics of the logic circuit provided by the individual test cell 728.

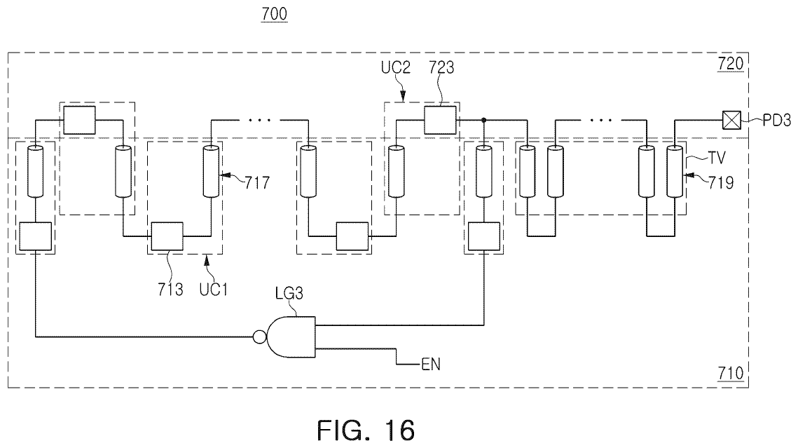

FIG. 16 illustrates a third ring oscillator included in the semiconductor device 700, the third ring oscillator outputting a second test clock signal to a third pad PD3, together with or instead of the second ring oscillator of FIG. 15. Referring to FIG. 16, the third ring oscillator may include a third logic gate LG3, a plurality of third lower reference cells 713, a plurality of third upper reference cells 723, a plurality of third via structures 717, and the like. An enable signal EN may be input to a first input terminal of the third logic gate LG3, and a raw clock signal may be fed back to a third input terminal of the third logic gate LG3.

The number of the plurality of third lower reference cells 713 may be the same as the number of the plurality of first lower reference cells 711, and a logic circuit provided by each of the plurality of third lower reference cells 713 may be the same as a logic circuit provided by each of the plurality of first lower reference cells 711. The number of the plurality of third upper reference cells 723 may be the same as the number of the plurality of first upper reference cells 721, and a logic circuit provided by each of the plurality of third upper reference cells 723 may be the same as a logic circuit provided by each of the plurality of first upper reference cells 721. At least one of the plurality of upper standard cells may provide the third logic gate LG3.

Accordingly, the raw clock signal, fed back to the second input terminal of the first logic gate LG1, may be the same as the raw clock signal, fed back to the third input terminal of the third logic gate LG3. In addition, in the third ring oscillator, a clock signal, input to a test circuit TV, may be a signal substantially the same as the reference clock signal, output by the first ring oscillator to the first pad PD1.

The second test clock signal, output to the third pad PD3, may have a frequency difference and/or a phase difference from the reference clock signal output to the first pad PD1. The second test clock signal may have the same frequency as the reference clock signal. For example, the frequency difference and/or the phase difference between the reference clock signal and the second test clock signal may be determined depending on the number of test via structures 719, included in the test circuit TV, and signal delay characteristics, caused by a resistance component, a capacitor component, or the like of each of the test via structures 719. In some implementations, a difference between one period of the reference clock signal and one period of the second test clock signal may be divided by the number of the test via structures 719, thereby determining signal delay characteristics appearing in an individual test via structure 719.

According to some implementations of the present disclosure, as described with respect to FIGS. 1-16, a semiconductor device, including semiconductor dies stacked on each other, may include a first ring oscillator generating a reference clock signal, and a second ring oscillator including cells and/or TSVs on which measurement of delay characteristics is to be performed. Frequencies and/or phases of a reference clock signal, output by the first ring oscillator, and a test clock signal, output by the second ring oscillator, may be compared to each other to accurately determine delay characteristics of the cells and/or the TSVs included in the semiconductor device, thereby performance and reliability of the semiconductor device based thereon.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been shown and described above, it will be apparent to those skilled in the art that modifications and variations could be made without departing from the scope of the present disclosure.

What is claimed is:

1. A semiconductor device comprising:
a lower semiconductor die including:
a lower substrate,
a plurality of lower standard cells disposed on the lower substrate,
a plurality of via structures extending in the lower substrate, and
a plurality of pads; and
an upper semiconductor die including:
an upper substrate, and
a plurality of upper standard cells disposed on the upper substrate, the upper semiconductor die stacked on the lower semiconductor die,
wherein a first plurality of standard cells, of the plurality of lower standard cells and the plurality of upper standard cells, include a first logic gate and a second logic gate,
wherein the first logic gate, first lower reference cells of the plurality of lower standard cells, first upper reference cells of the plurality of upper standard cells, and first via structures of the plurality of via structures, together form a first ring oscillator,
wherein the second logic gate, second lower reference cells of the plurality of lower standard cells, second upper reference cells of the plurality of upper standard cells, second via structures of the plurality of via structures, and a test circuit connected between the second via structures and an input terminal of the second logic gate, together form a second ring oscillator, and
wherein the first ring oscillator is configured to output a reference clock signal to a first pad of the plurality of pads, and the second ring oscillator is configured to output a test clock signal to a second pad of the plurality of pads.

2. The semiconductor device of claim 1, wherein the test circuit includes lower test cells, and wherein the lower test cells include lower standard cells of the plurality of lower standard cells.

3. The semiconductor device of claim 1, wherein the test circuit includes upper test cells, and wherein the upper test cells include upper standard cells of the plurality of upper standard cells.

4. The semiconductor device of claim 1, wherein the test circuit includes test via structures, and wherein the test via structures include via structures of the plurality of via structures.

5. The semiconductor device of claim 1, wherein:
an output terminal of the first logic gate is directly connected to one of the first lower reference cells, the first upper reference cells, or the first via structures, and
an output terminal of the second logic gate is directly connected to one of the second lower reference cells, the second upper reference cells, or the second via structures.

6. The semiconductor device of claim 5, wherein respective input terminals of the first logic gate and the second logic gate are configured to receive an enable signal.

7. The semiconductor device of claim 1, wherein:
a number of the first lower reference cells is equal to a number of the second lower reference cells,
a number of the first upper reference cells is equal to a number of the second upper reference cells, and
a number of the first via structures is equal to a number of the second via structures.

8. The semiconductor device of claim 7, wherein:
each of the first lower reference cells includes a logic circuit that is configured to operate the same as a logic circuit included in each of the second lower reference cells, and
each of the first upper reference cells includes a logic circuit that is configured to operate the same as a logic circuit included in each of the second upper reference cells.

9. The semiconductor device of claim 1, wherein:
each of the first logic gate and the second logic gate is a NAND gate, and
each of the first lower reference cells, the first upper reference cells, the second lower reference cells, and the second upper reference cells is a non-inverting cell.

10. The semiconductor device of claim 1, wherein:
each of the first logic gate and the second logic gate is a NOR gate or an AND gate,
each of the first lower reference cells, the first upper reference cells, the second lower reference cells, and the second upper reference cells is an inverting cell, and
a total number of the first lower reference cells and the first upper reference cells is odd, and a total number of the second lower reference cells and the second upper reference cells is odd.

11. The semiconductor device of claim 1, wherein
the first ring oscillator includes a first divider connected to the first pad, and
the second ring oscillator includes a second divider connected to the second pad.

12. The semiconductor device of claim 1, wherein each of the first lower reference cells, the first upper reference cells, the second lower reference cells, and the second upper reference cells comprises a circuit configured to input and output a signal through the first via structures or the second via structures.

13. A semiconductor device comprising:
a lower semiconductor die including:
a lower element region including a plurality of lower elements disposed on a lower substrate,
a lower interconnection region disposed on the lower element region, and
a plurality of lower via structures extending in the lower substrate; and
an upper semiconductor die including:
an upper element region including a plurality of upper elements disposed on an upper substrate, and
an upper interconnection region disposed on the upper element region, the upper semiconductor die stacked on the lower semiconductor die in a first direction,
wherein (i) first lower elements of the plurality of lower elements and (ii) first upper elements of the plurality of upper elements together form:
a first ring oscillator configured to output a reference clock signal generated on a signal transmission path that includes first via structures of the plurality of lower via structures, and
a second ring oscillator configured to output a test clock signal generated on a signal transmission path that includes second via structures, different from the first via structures, of the plurality of via structures.

14. The semiconductor device of claim 13, wherein, along the first direction, the upper interconnection region is arranged between the lower element region and the upper element region.

15. The semiconductor device of claim 14, wherein, along the first direction, the upper interconnection region and the lower interconnection region are disposed between the lower element region and the upper element region.

16. The semiconductor device of claim 13, wherein a number of the first via structures is equal to a number of the second via structures.

17. The semiconductor device of claim 13, wherein the lower element region or the upper element region includes:
a first logic gate included in the first ring oscillator, and
a second logic gate included in the second ring oscillator.

18. The semiconductor device of claim 17, wherein the lower interconnection region or the upper interconnection region includes:
a first pad to which the reference clock signal is output, and
a second pad to which the test clock signal is output.

19. A semiconductor device including a lower semiconductor die and an upper semiconductor die stacked on one another, the semiconductor device comprising:
a first ring oscillator including:
first lower unit circuits included in first lower standard cells of lower standard cells, the lower standard cells being included in the lower semiconductor die,
first upper unit circuits included in first upper standard cells of upper standard cells, the upper standard cells being included in the upper semiconductor die, wherein the first upper unit circuits and the first lower unit circuits are alternately connected to one another, and
a first logic gate having a first input terminal configured to receive an enable signal and a second input terminal connected to one of the first lower unit circuits or the first upper unit circuits; and
a second ring oscillator including:
second lower unit circuits included in second lower standard cells of the lower standard cells,
second upper unit circuits included in second upper standard cells of the upper standard cells, wherein the second upper unit circuits and the second lower unit circuits are alternately connected to one another,
a second logic gate having a first input terminal configured to receive the enable signal and a second input terminal connected to one of the second lower unit circuits or the second upper unit circuits, and
a test circuit configured to delay a raw clock signal input to the second input terminal of the second logic gate.

20. The semiconductor device of claim 19, wherein:
the first ring oscillator is configured to output a reference clock signal input to the second input terminal of the first logic gate to a first pad, and
the second ring oscillator is configured to output a test clock signal, comprising the raw clock signal having been delayed by the test circuit, to a second pad.
